(19) United States
(12) Patent Application Publication
(10) Pub. No.: US 2009/0196979 A1
(43) Pub. Date: Aug. 6, 2009

(54) INKJET PRINTING PROCESS FOR CIRCUIT BOARD

(75) Inventors: Shih-Lian Cheng, Hsinchu (TW); Hung-Sen Wei, Hsinchu (TW)

Correspondence Address: J C PATENTS, INC., 4 VENTURE, SUITE 250, IRVINE, CA, 92618, US

(73) Assignee: SUBTRON TECHNOLOGY CO. LTD., Hsinchu (TW)

(21) Appl. No.: 12/208,636

(22) Filed: Sep. 11, 2008

(30) Foreign Application Priority Data
Feb. 5, 2008 (TW) 97104604

(51) Int. Cl. H05K 3/06

(52) U.S. Cl. 427/97.3

(57) ABSTRACT

An inkjet printing process for a circuit board includes the following procedures. Firstly, a substrate and a conductive layer disposed on the substrate are provided. Afterward, a roughening treatment is performed on the conductive layer so that the roughness of the conductive layer is between 0.1 μm and 5 μm. Then, a patterned mask layer is printed on the conductive layer for covering an area of the conductive layer prepared for forming a circuit pattern.

### CROSS-REFERENCE TO RELATED APPLICATION

This application claims the priority benefit of Taiwan application serial no. 97104604, filed on Feb. 5, 2008. The entirety of the above-mentioned patent application is hereby incorporated by reference herein and made a part of specification.

### BACKGROUND OF THE INVENTION

1. Field of the Invention

The present invention generally relates to a circuit board, in particular, to an inkjet printing process for a circuit board.

2. Description of Related Art

The method of forming a predetermined mask pattern by means of an inkjet printing process in the prior art has the following advantages. For example, in the absence of mask or screen, merely a single procedure is needed to print the mask layer into a demanded pattern (including characters, regular or irregular complicated circuit patterns), so that the patterned circuit may be more conveniently manufactured, and the duration of the process may be shortened. Moreover, the patterned mask layer may be formed directly by means of the inkjet printing process without requiring the procedures such as exposure and development. Therefore, the developer and cleaning solution are not needed in the inkjet printing process, and the consuming amount of drops for the inkjet printing process is less than that of the photoresist in the lithography process, so as to inhibit the environmentally friendly problems. In addition, the inkjet printing process utilizes less equipment and has a high material utilization rate and a short process period, so as to achieve a low process cost.

FIG. 1 is a schematic view of a patterned mask layer fabricated by an inkjet printing process according to the prior art. Referring to FIG. 1, in the inkjet printing process of the prior art, the drops printed on the conductive layer 110 (not shown) may not easily combine, the patterned mask layer 120 composed of the drops on the conductive layer 110 has an obvious grain and is not quite uniform, and the patterned mask layer 120 is unsmooth at the edge of the pattern. Thereby, the accuracy of the pattern of the patterned mask layer 120 is affected, and the accuracy of the pattern of the patterned conductive layer (not shown) formed by etching the conductive layer 110 with the patterned mask layer 120 as mask is further affected. Further, the electrical quality of the subsequently formed circuit board is decreased.

### SUMMARY OF THE INVENTION

The present invention is directed to an inkjet printing process for a circuit board, which prints drops on roughened conductive layer, so as to make the drops to be uniform without grain and be smooth at the edge.

As embodied and broadly described herein, the present invention provides an inkjet printing process for a circuit board. Firstly, a substrate and a conductive layer disposed on the substrate are provided. Then, a roughening treatment is performed on the conductive layer, so that the roughness of the conductive layer is between 0.1 μm and 5 μm. Afterward, a patterned mask layer is printed on the conductive layer for covering an area of the conductive layer prepared for forming a circuit pattern.

In an embodiment of the present invention, the material of the conductive layer includes copper.

In an embodiment of the present invention, the roughening treatment is substantially a physical roughening treatment or a chemical roughening treatment.

In an embodiment of the present invention, the physical roughening treatment includes grinding the conductive layer with non-woven fabric, abrasive belt, or ceramics.

In an embodiment of the present invention, the physical roughening treatment includes sand blasting.

In an embodiment of the present invention, the chemical roughening treatment includes making the conductive layer react with a sodium thiosulfate solution.

In an embodiment of the present invention, the chemical roughening treatment includes making the conductive layer react with a solution containing sulfuric acid and hydrogen peroxide.

The present invention performs the roughening treatment on the conductive layer to change the roughness of the surface of the conductive layer, so as to combine the drops printed on the conductive layer to form a patterned mask layer. Since the drops printed on the conductive layer may more easily combine, the patterned mask layer in the present invention is more uniform without grain and be smooth at the edge, and the accuracy of the pattern is higher.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a patterned mask layer fabricated by an inkjet printing process according to the prior art.

FIG. 2 is a schematic view of an inkjet printing process for a circuit board according to an embodiment of the present invention.

FIG. 3 is a top view of a patterned mask layer printed on the roughened conductive layer in FIG. 2.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

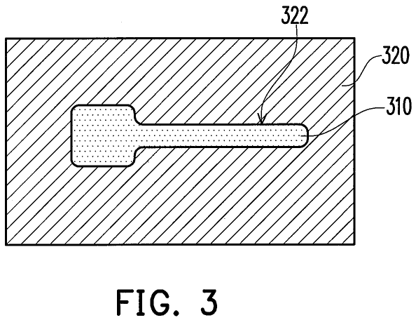

FIG. 2 is a schematic view of an inkjet printing process for a circuit board according to an embodiment of the present invention. FIG. 3 is a top view of a patterned mask layer printed on the roughened conductive layer in FIG. 2.

Referring to FIG. 2, in Step S210, a substrate and a conductive layer disposed on the substrate are provided. The substrate may be a single-layer dielectric substrate or a circuit substrate containing at least one circuit layer. The conductive layer is, for example, made of copper or other appropriate conductive materials.

Next, referring to FIG. 2, in Step S220 or Step S230, a roughening treatment is performed on the conductive layer, so that the roughness of the conductive layer is between 0.1 μm and 5 μm, and further the drops (not shown) printed on the conductive layer may more easily combine to form a patterned mask layer (not shown). The roughening treatment is substantially a chemical roughening treatment (Step S220) or a physical roughening treatment (Step S230). The chemical roughening treatment may be making the conductive layer react with a sodium thiosulfate solution. In addition, the chemical roughening treatment may also be making the conductive layer react with a solution containing sulfuric acid and hydrogen peroxide. The chemical roughening treatment is, for example, brown oxide or black oxide.

The physical roughening treatment includes grinding the conductive layer with grinding materials such as non-woven fabric, abrasive belt or ceramics. The non-woven fabric grinding material may be combined of high-tenacity fabric, grinding ore, and special adhesive. The abrasive belt grinding material is combined of grinding ore and special adhesive. The grinding ore usually includes aluminum oxide, titania, silicon carbide, talc, and the like, and has a particle diameter usually being between 5 μm and 60 μm. The ceramics grinding material is formed by sintering high-purity aluminum oxide powder. Moreover, the physical roughening treatment may also be sand blasting. The particle diameter of the sand blasting particle is between 5 and 100 μm.

Afterward, referring to FIGS. 2 and 3, a patterned mask layer 310 is printed on a conductive layer 320 for covering an area 322 of the conductive layer 320 prepared for a circuit pattern (Step S240). Meanwhile, the patterned mask layer 310 is accomplished initially. In this embodiment, a curing process may be further performed on the patterned mask layer 310. The curing process is, for example, baking.

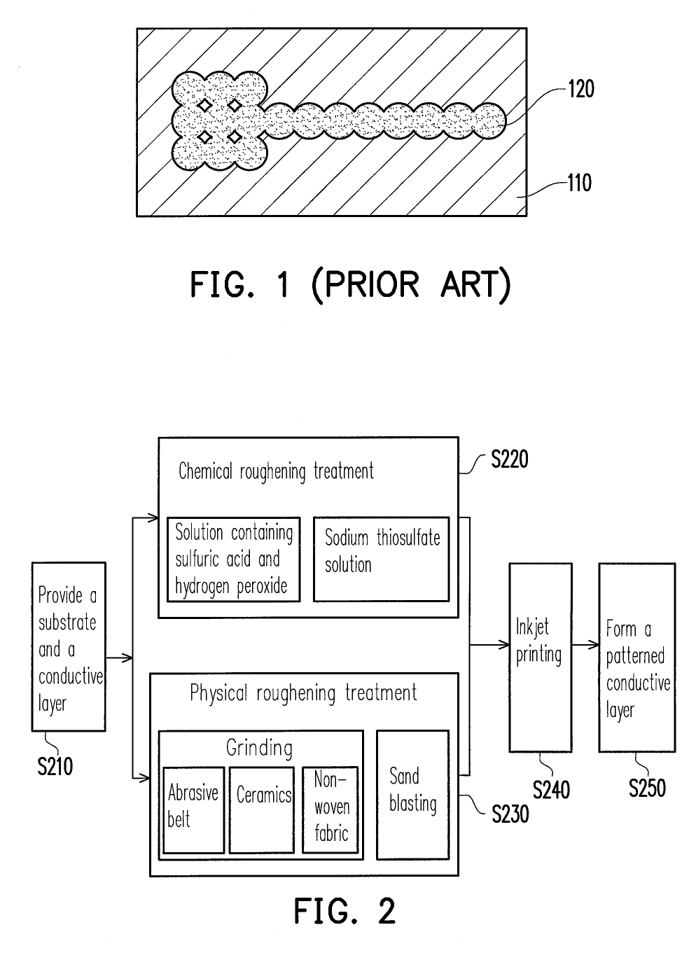

In view of the above, in this embodiment, a roughening treatment is performed on the conductive layer 320 to change the roughness on the surface of the conductive layer 320, so that the drops (not shown) printed on the conductive layer 320 may easily combine to form the patterned mask layer 310. Compared with the patterned mask layer 120 in the prior art (see FIG. 1), in this embodiment, the drops printed on the conductive layer 320 may more easily combine. Therefore, the patterned mask layer 310 in this embodiment is uniform without grain, and is smooth at the edge of the pattern. Hence, the pattern of the patterned mask layer 310 in this embodiment has a higher accuracy.

Based on the above, the spirit of this embodiment lies in performing a roughening treatment on the conductive layer to change the roughness of the surface of the conductive layer, so that the drops printed on the conductive layer may easily combine to form a uniform patterned mask layer which is smooth at the edge of the pattern, and persons skilled in the art can make any alternations and modifications without going beyond the spirit and scope of this embodiment.

Furthermore, in this embodiment, the following procedures may be performed to form a patterned conductive layer. Referring to FIGS. 2 and 3, the portion of the conductive layer 320 which is not covered by the patterned mask layer 310 is removed to form a patterned conductive layer (Step S250). The method of removing the conductive layer 320 includes etching. Since the pattern of the patterned mask layer 310 in this embodiment has a high accuracy, the patterned conductive layer in this embodiment also has a high pattern accuracy, such that the electrical quality of the subsequently formed circuit board is improved.

Then, in this embodiment, after the patterned conductive layer is formed, the patterned mask layer 310 may be removed. In addition, the method of removing the patterned mask layer 310 includes etching.

Based on the above, in the present invention, a roughening treatment is performed on the conductive layer to change the roughness of the surface of the conductive layer, so that the drops printed on the conductive layer may easily combine to form the patterned mask layer. Since the drops printed on the conductive layer may more easily combine, the patterned mask layer in the present invention is uniform without grain, and is smooth at the edge of the pattern. Hence, the patterned mask layer in the present invention has a higher pattern accuracy, and thus the electrical quality of the subsequently formed circuit board is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An inkjet printing process for a circuit board, comprising:
providing a substrate and a conductive layer disposed on the substrate;
performing a roughening treatment on the conductive layer, so that roughness of the conductive layer is between 0.1 μm and 5 μm; and
printing a patterned mask layer on the conductive layer for covering an area of the conductive layer prepared for forming a circuit pattern.

2. The inkjet printing process for a circuit board according to claim 1, wherein a material of the conductive layer comprises copper.

3. The inkjet printing process for a circuit board according to claim 1, wherein the roughening treatment is substantially a physical roughening treatment or a chemical roughening treatment.

4. The inkjet printing process for a circuit board according to claim 3, wherein the physical roughening treatment comprises grinding the conductive layer with non-woven fabric, abrasive belt, or ceramics.

5. The inkjet printing process for a circuit board according to claim 3, wherein the physical roughening treatment comprises sand blasting.

6. The inkjet printing process for a circuit board according to claim 3, wherein the chemical roughening treatment comprises making the conductive layer react with a sodium thiosulfate solution.

7. The inkjet printing process for a circuit board according to claim 3, wherein the chemical roughening treatment comprises making the conductive layer react with a solution containing sulfuric acid and hydrogen peroxide.
